(19) United States
(12) Patent Application Publication
(10) Pub. No.: US 2026/0039301 A1
(43) Pub. Date: Feb. 5, 2026

(54) DRIVING DEVICE, ELECTRONIC DEVICE, AND VEHICLE

(71) Applicant: ROHM CO., LTD., Kyoto-shi (JP)

(72) Inventor: Masahiko ARIMURA, Kyoto-shi (JP)

(21) Appl. No.: 19/278,141

(22) Filed: Jul. 23, 2025

(30) Foreign Application Priority Data
Jul. 31, 2024 (JP) 2024-124472

(51) Int. Cl. H03K 19/08; B60R 16/023; H02H 3/08; H03K 3/017

(52) U.S. Cl. CPC H03K 19/08; H02H 3/08; H03K 3/017; B60R 16/0239

(57) ABSTRACT

A driving device includes: for example, a supply circuit configured to generate a supply voltage; a driving circuit configured to generate a driving signal for a switching device by being supplied with the supply voltage; and a logic circuit configured to control the driving circuit according to a first input signal and a second input signal. The supply circuit sets the supply voltage to a first voltage value in a first mode and sets the supply voltage to one of a second voltage value that is less than the first voltage value and the first voltage value in a second mode. The logic circuit enables the second input signal in the first mode and disables the second input signal in the second mode.

### CROSS REFERENCE TO RELATED APPLICATIONS

The present invention claims priority under 35 U.S.C. § 119 to Japanese Patent Application No. 2024-124472 filed on Jul. 31, 2024, the contents of which are hereby incorporated by reference.

### BACKGROUND

### 1. Technical Field

The present disclosure relates to a driving device, an electronic device, and a vehicle.

### 2. Description of Related Art

Hitherto, driving devices that drive, and control power transistors are used in various applications (e.g., power supply devices and motor driving devices).

Note that International Publication No. WO-A-2022/070944, which is another disclosure by the present applicant, can be cited as one example of the related art that relates to the above description.

### BRIEF DESCRIPTION OF THE DRAWINGS

FIG. 1 is a diagram illustrating the basic configuration of a signal transmission device;

FIG. 2 is a diagram illustrating the basic structure of a transformer chip;

FIG. 3 is a perspective view of a semiconductor device used as a two-channel transformer chip;

FIG. 4 is a plan view of the semiconductor device shown in FIG. 3;

FIG. 5 is a plan view of a layer in the semiconductor device shown in FIG. 3 where low-potential coils are formed;

FIG. 6 is a plan view of a layer in the semiconductor device shown in FIG. 3 where high-potential coils are formed;

FIG. 7 is a cross-sectional view taken along line VIII-VIII shown in FIG. 6;

FIG. 8 is an enlarged view (showing a separation structure) of region XIII shown in FIG. 7;

FIG. 9 is a diagram schematically showing an example of the layout of a transformer chip;

FIG. 10 is a diagram showing a comparative example of an electronic device;

FIG. 11 is a diagram showing an embodiment of the electronic device;

FIG. 12 is a diagram showing a configuration example of a driving device;

FIG. 13 is a flowchart showing active discharge;

FIG. 14 is a chart showing a first example of the active discharge;

FIG. 15 is a chart showing a second example of the active discharge; and

FIG. 16 is an exterior view of a vehicle.

### DETAILED DESCRIPTION

### Signal Transmission Device (Basic Configuration)

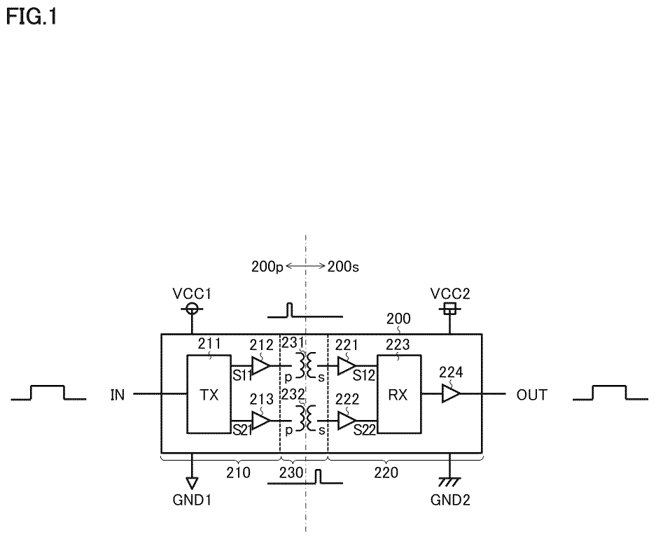

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts), and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

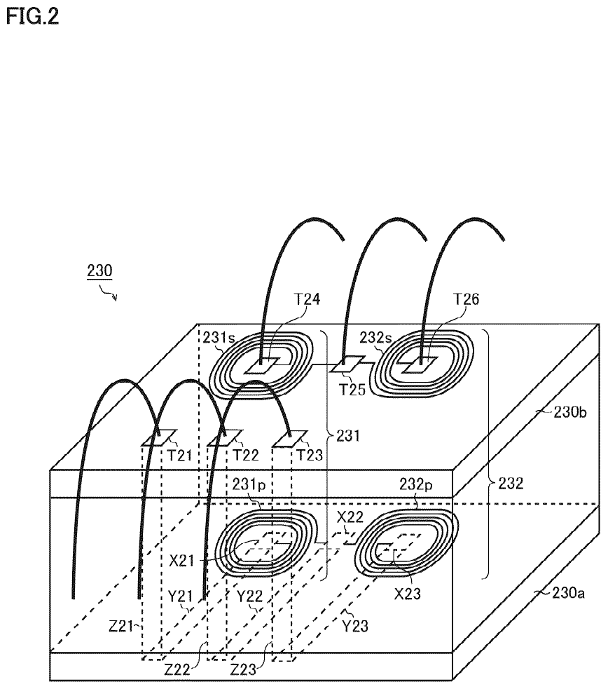

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230 and is DC-isolated from the controller chip 210 by the transformer chip 230.

### Transformer Chip (Two-Channel Type)

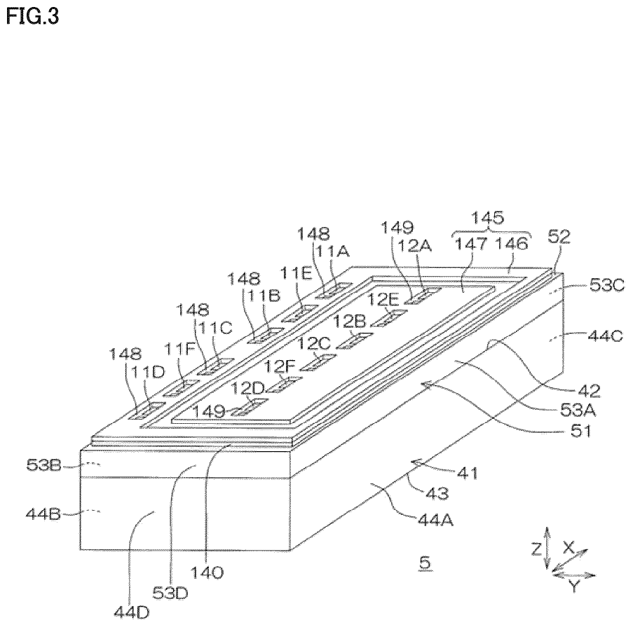

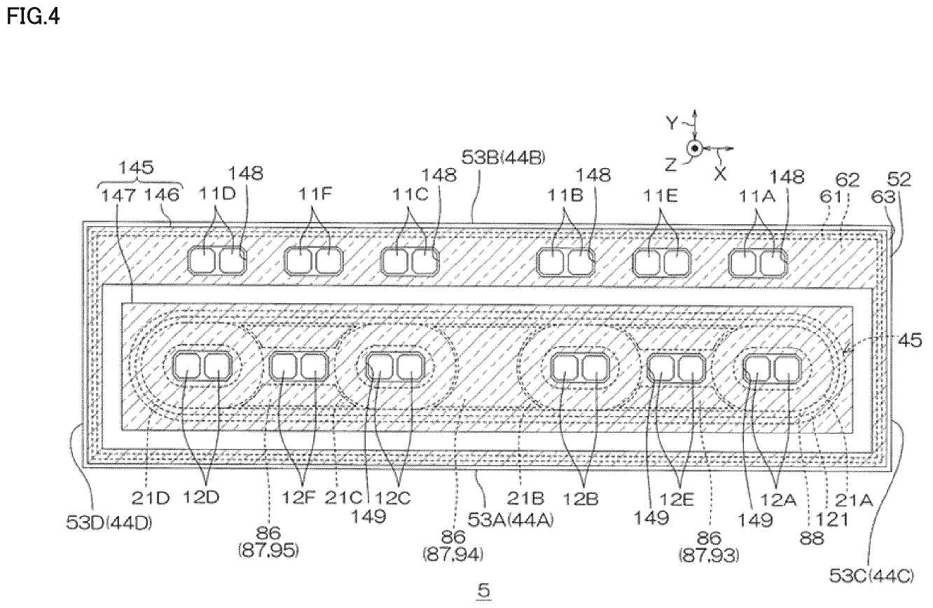

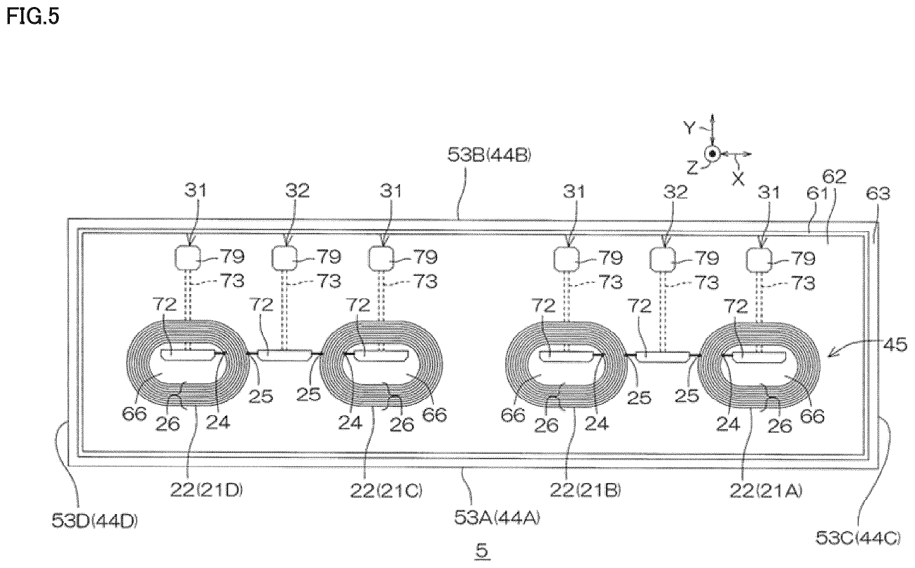

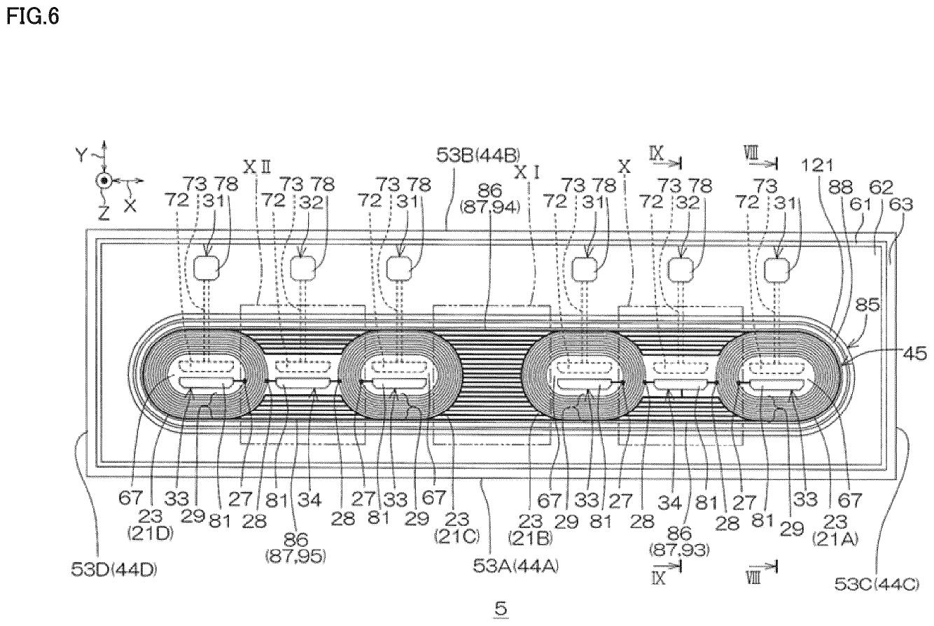

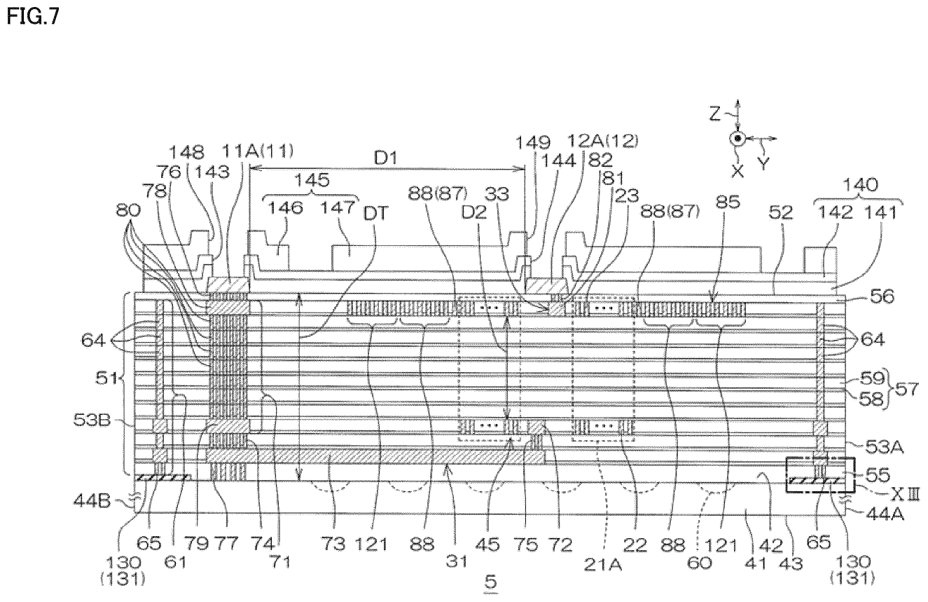

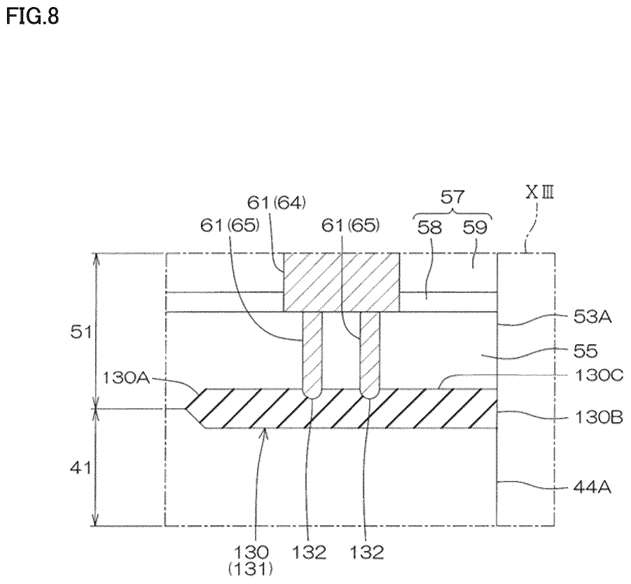

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIGS. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41 and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58, and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIGS. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 1IF is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41 and extends in the shape of a stripe in a region between the first and second end parts.

The first connection plug electrode 74 is formed in the interlayer insulation layer 57, in a region between the through wiring 71 and the lead wiring 73 and is electrically connected to the through wiring 71 and to the first end part of the lead wiring 73. The second connection plug electrode 75 is formed in the interlayer insulation layer 57, in a region between the low-potential connection wiring 72 and the lead wiring 73 and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71 and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73 and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81 and are electrically connected to the high-potential terminal 12 and to the high-potential connection wiring 81. The plurality of pad plug electrodes 82 each have a plane arca smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22 and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit arca that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effective electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41 and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIGS. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively and are each formed in a quadrangular ring shape (specifically, a rectangular ring shape) surrounding the device region 62. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41 and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area equal to or larger than the plane arca of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41 and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41 and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61 and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146 and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low-and high-potential terminals 11 and 12, it is possible to suppress unnecessary conduction between the high-potential terminal 12 and the sealing conductor 61. Likewise, in a case where a voltage is applied to the second functional device 60 via the low-and high-potential terminals 11 and 12, it is possible to suppress unnecessary conduction between the low-potential terminal 11 and the sealing conductor 61.

The embodiment described above deals with an example where a second functional device 60 is formed. The second functional device 60 however is not essential and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

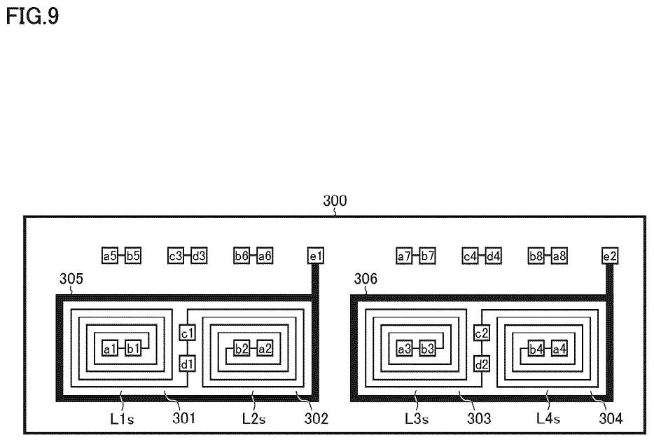

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively and are disposed right below the secondary coils L1s to LAs, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads al to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are however not essential elements.

The first and second guard rings 305 and 306 can be connected via pads e1 and c2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Electronic Device (Comparative Example)

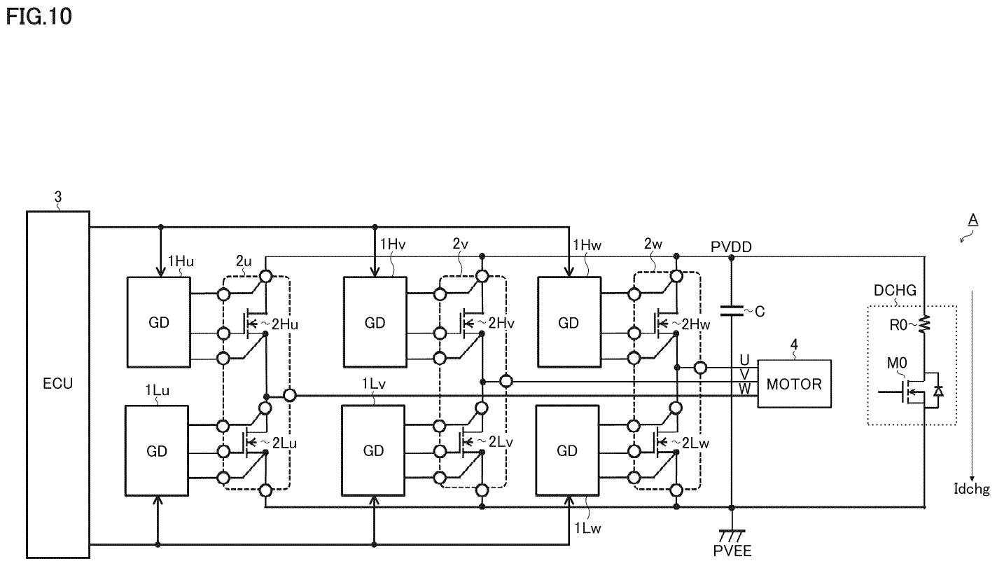

FIG. 10 is a diagram showing a comparative example of an electronic device A (corresponding to an example of a configuration to be compared with an embodiment described subsequently). The electronic device A includes high-side gate driver ICs 1H(u/v/w), low-side gate driver ICs 1L(u/v/w), high-side power transistors 2H(u/v/w), low-side power transistors 2L(u/v/w), and an ECU [electronic control unit] 3, a motor 4, and a capacitor C.

The high-side gate driver ICs 1H(u/v/w) respectively drive the high-side power transistors 2H(u/v/w) by generating high-side gate-driving signals according to high-side gate control signals to be input from the ECU 3 while isolating between the ECU 3 and the high-side power transistors 2H(u/v/w). The high-side gate driver ICs 1H(u/v/w) can be understood respectively as high-side driving devices.

The low-side gate driver ICs 1L(u/v/w) respectively drive the low-side power transistors 2L(u/v/w) by generating low-side gate-driving signals according to low-side gate control signals to be input from the ECU 3 while isolating between the ECU 3 and the low-side power transistors 2L(u/v/w). The low-side gate driver ICs 1L(u/v/w) can be understood respectively as low-side driving devices.

Note that the signal transmission device 200 described previously can be suitably used as the high-side gate driver ICs 1H(u/v/w) and the low-side gate driver ICs 1L(u/v/w) described above.

The high-side power transistors 2H(u/v/w) are connected between an application terminal for a first supply voltage PVDD and input terminals for respective phases of the motor 4 as high-side switching devices that respectively form half-bridge output stages 2(u/v/w) for three phases (U-phase/V-phase/W-phase).

The low-side power transistors 2L(u/v/w) are connected between the input terminals for the respective phases of the motor 4 and an application terminal for a second supply voltage PVEE as low-side switching devices that respectively form the half-bridge output stages 2(u/v/w) for the three phases (U-phase/V-phase/W-phase).

The high-side power transistors 2H(u/v/w) and the low-side power transistors 2L(u/v/w) may each be a MOS [metal oxide semiconductor] transistor formed as a Si device, a SiC device, or a GaN device. Alternatively, the high-side power transistors 2H(u/v/w) and the low-side power transistors 2L(u/v/w) may each be replaced with an IGBT [insulated gate bipolar transistor]. Note that the half-bridge output stages 2(u/v/w) may be provided as power modules.

The ECU 3 controls rotation and driving of the motor 4 by driving the high-side power transistors 2H(u/v/w) and the low-side power transistors 2L(u/v/w) respectively via the high-side gate driver ICs 1H(u/v/w) and the low-side gate driver ICs 1L(u/v/w).

The motor 4 may be a three-phase motor that is driven to rotate according to three-phase driving voltages U/V/W to be respectively input via the half-bridge output stages 2(u/v/w) for the three phases (U-phase/V-phase/W-phase).

The capacitor C is connected in parallel to the half-bridge output stages 2(u/v/w) between the application terminal for the first supply voltage PVDD and the application terminal for the second supply voltage PVEE. The capacitor C can be understood as a DC [direct current] link capacitor for smoothing the first supply voltage PVDD. A capacitance value of the capacitor C may be, for example, 500 μF to 2000 μF.

In this way, the signal transmission device 200 (isolated gate driver IC) is applicable, for example, to inverter circuits for motor driving.

### Investigation of Discharge from Capacitor C

Incidentally, in vehicle-mounted inverter circuits, the capacitor C maintaining a high voltage (e.g., several hundred volts) need be discharged before maintenance of the vehicles. Thus, a discharge circuit DCHG is provided in the electronic device A. The discharge circuit DCHG commonly includes a high-withstand-voltage switch M0 for short-circuiting between the application terminal for the first supply voltage PVDD and the application terminal for the second supply voltage PVEE, and a current limiting resistor R0 for limiting a discharge current Idchg that flows through the high-withstand-voltage switch M0. The high-withstand-voltage switch M0 may be, for example, a power device. The current limiting resistor R0 may be, for example, a cement resistor.

In order that a high voltage is rapidly discharged within a shortest-possible time (e.g., 1 s or less), the discharge current Idchg which is high need flow through the discharge circuit DCHG. Thus, parts that have high thermal tolerance need be used as the high-withstand-voltage switch M0 and the current limiting resistor R0. Such parts are commonly large and expensive.

In view of the investigation described above, in the following description, an embodiment in which the capacitor C can be discharged without the need for the discharge circuit DCHG is proposed.

### Electronic Device (Embodiment)

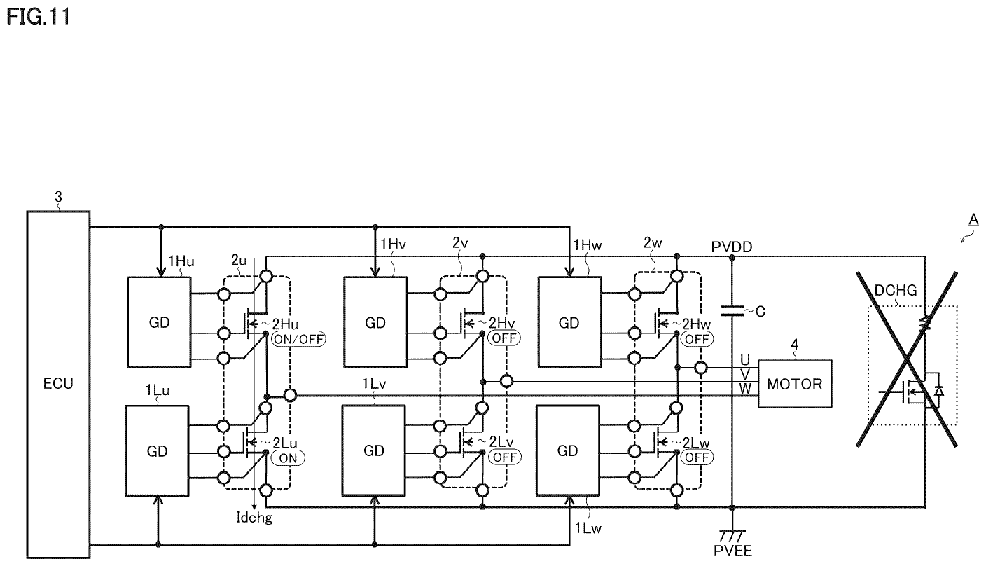

FIG. 11 is a diagram showing an embodiment of the electronic device A. The electronic device A of this embodiment is basically the same as that of the comparative example (FIG. 10) described previously except having what is generally called an active discharge function that is a function to discharge the capacitor C by using any one of the half-bridge output stages 2(u/v/w), that is, the half-bridge output stage 2u for the U-phase in the diagram.

For example, in order that the capacitor C is subjected to the active discharge, the high-side power transistor 2Hu and the low-side power transistors 2Lu for the U-phase are turned on together. Specifically, the high-side power transistor 2Hu can be turned on/off under a state in which a gate-to-source voltage Vgs (2Hu) to be applied in an on-period Ton is pulled down to be lower than that in normal operation, that is, under a state in which the discharge current Idchg that flows in the on-period Ton of the high-side power transistor 2Hu is suppressed. By contrast, the low-side power transistor 2Lu can be kept on.

On the other hand, the high-side power transistor 2Hv and the low-side power transistor 2Lv for the V-phase, and the high-side power transistor 2Hw and the low-side power transistor 2Lw for the W-phase can all be kept off.

Such active discharge eliminates the need for the discharge circuit DCHG described previously, and hence downsizing and cost reduction of the electronic device A can be achieved.

In the following description, a driving device 400 that can be utilized as the high-side gate driver ICs 1H(u/v/w) and the low-side gate driver ICs 1L(u/v/w) is proposed.

### Driving Device

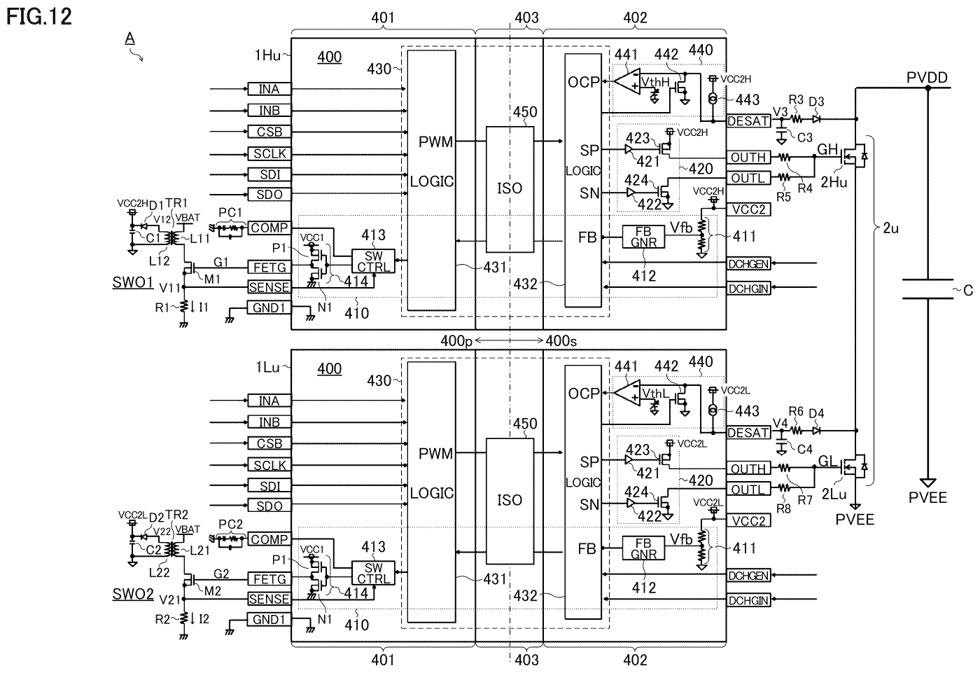

FIG. 12 is a diagram showing a configuration example of the driving device 400. The driving device 400 of this configuration example can be utilized, for example, as the high-side gate driver IC 1Hu and the low-side gate driver IC 1Lu for the U-phase to be incorporated in the electronic device A. That is, the electronic device A includes the same driving devices 400 as the high-side gate driver IC 1Hu and the low-side gate driver IC 1Lu.

The high-side power transistor 2Hu and the low-side power transistor 2Lu correspond respectively to a high-side switching device and a low-side switching device that form the half-bridge output stage by being connected in series between the application terminal for the first supply voltage PVDD and the application terminal for the second supply voltage PVEE. The high-side gate driver IC 1Hu corresponds to a high-side driving device that drives the high-side power transistor 2Hu. The low-side gate driver IC 1Lu corresponds to a low-side driving device that drives the low-side power transistor 2Lu.

The driving device 400 is a semiconductor integrated circuit device (what is generally called an isolated gate driver IC) that, while electrically isolating between a primary circuit system 400p (VCC1-GND1 system) and a secondary circuit system 400s (VCC2-GND2 system), transmits a driving pulse signal PWM from the primary circuit system 400p to the secondary circuit system 400s to drive the respective gates of the high-side power transistor 2Hu and the low-side power transistor 2Lu provided in the secondary circuit system 400s.

Note that the driving device 400 can be understood as corresponding to the signal transmission device 200 described previously. That is, the driving device 400 can be employed widely in applications in general that require signal transmission between the primary circuit system 400p and the secondary circuit system 400s while isolating between them (such as motor drivers and DC/DC converters that handle high voltages).

The driving device 400 includes, as means for establishing electrical connection to the outside of the device, a plurality of external terminals, of which the diagram shows input terminals INA and INB, a chip select terminal CSB, a clock input terminal SCLK, a serial-data input terminal SDI, a serial-data output terminal SDO, a phase compensation terminal COMP, a gate-driving terminal FETG, a sense terminal SENSE, a grounded terminal GND1, an overcurrent detection terminal DESAT, output terminals OUTH and OUTL, a power terminal VCC2, and mode switching terminals DCHGEN and DCHGIN. Note that other external terminals that are not explicitly shown in the diagram may be provided to the driving device 400.

Along a first side of a package that forms the driving device 400 (corresponding to the left-hand side in the diagram), from top down, the input terminal INA, the input terminal INB, the chip select terminal CSB, the clock input terminal SCLK, the serial-data input terminal SDI, the serial-data output terminal SDO, the phase compensation terminal COMP, the gate-driving terminal FETG, the sense terminal SENSE, and the grounded terminal GND1 are arrayed. In this way, it is appropriate for the external terminals in the primary circuit system 400p (INA, INB, CSB, SCLK, SDI, SDO, COMP, FETG, SENSE, and GND1) to be arrayed together along the first side of the package.

On the other hand, along a second side of the same package (corresponding to a side that faces the first side described above, that is, to the right-hand side in the diagram), from top down, the overcurrent detection terminal DESAT, the output terminal OUTH, the output terminal OUTL, the power terminal VCC2, the mode switching terminal DCHGEN, and the mode switching terminal DCHGIN are arrayed. In this way, it is appropriate for the output terminals in the secondary circuit system 400s (DESAT, OUTH, OUTL, VCC2, DCHGEN, and DCHGIN) to be arrayed together along the second side of the package.

Next, discrete parts that are externally connected to the driving device 400 will be described. In terms of what is shown in the diagram, not only the high-side power transistor 2Hu and the low-side power transistor 2Lu, but also capacitors C1, C2, C3, and C4, diodes D1, D2, D3, and D4, transistors M1 and M2, phase compensation circuits PC1 and PC2, resistors R1, R2, R3, R4, R5, R6, R7, and R8, and transformers TR1 and TR2 are externally connected directly or indirectly to the high-side gate driver 1C 1Hu and the low-side gate driver IC 1Lu. The transistors M1 and M2 may be, for example, of an N-channel type.

First, description will be given with a focus on the high-side gate driver IC 1Hu. The phase compensation circuit PC1 is connected to the phase compensation terminal COMP. The phase compensation circuit PC1 may be a time constant circuit including a resistor and a capacitor. The gate-driving terminal FETG is connected to the gate of the transistor M1. The sense terminal SENSE is connected to the source and the backgate of the transistor M1 and the first terminal of the resistor R1. The grounded terminal GND1 and the second terminal of the resistor R1 are both connected to a grounded terminal of the primary circuit system 400p.

The transformer TR1 includes a primary coil L11 (a number of turns of N11) and a secondary coil L12 (a number of turns of N12) that are electromagnetically coupled to each other while electrically isolating between the primary circuit system 400p and the secondary circuit system 400s.

The first terminal (e.g., a winding start terminal) of the primary coil L11 is connected to an application terminal for an input voltage VBAT. The second terminal (e.g., a winding end terminal) of the primary coil L11 is connected to the drain of the transistor M1. The first terminal (e.g., a winding end terminal) of the secondary coil L12 is connected to the anode of the diode D1. The cathode of the diode D1 and the first terminal of the capacitor C1 are connected to an application terminal for a supply voltage VCC2H. The second terminal (e.g., a winding start terminal) of the secondary coil L12 and the second terminal of the capacitor C1 are both connected to a grounded terminal of the secondary circuit system 400s.

Note that the transistor M1, the transformer TR1, the diode D1, and the capacitor C1 form a flyback switching output stage SWO1 that generates the supply voltage VCC2H for the secondary circuit system 400s from the input voltage VBAT in the primary circuit system 400p while isolating between the primary circuit system 400p and the secondary circuit system 400s.

The overcurrent detection terminal DESAT is connected to the respective first terminals of the resistor R3 and the capacitor C3. The second terminal of the capacitor C3 is connected to the grounded terminal of the secondary circuit system 400s. The second terminal of the resistor R3 is connected to the anode of the diode D3. The cathode of the diode D3 is connected to the drain of the high-side power transistor 2Hu.

The output terminal OUTH is connected to the first terminal of the resistor R4. The output terminal OUTL is connected to the first terminal of the resistor R5. The respective second terminals of the resistors R4 and R5 are connected to the gate of the high-side power transistor 2Hu.

Next, description will be given with a focus on the low-side gate driver IC 1Lu. The phase compensation circuit PC2 is connected to the phase compensation terminal COMP. The phase compensation circuit PC2 may be a time constant circuit including a resistor and a capacitor. The gate-driving terminal FETG is connected to the gate of the transistor M2. The sense terminal SENSE is connected to the source and the backgate of the transistor M2 and the first terminal of the resistor R2. The grounded terminal GND1 and the second terminal of the resistor R2 are both connected to the grounded terminal of the primary circuit system 400p.

The transformer TR2 includes a primary coil L21 (a number of turns of N21) and a secondary coil L22 (a number of turns of N22) that are electromagnetically coupled to each other while electrically isolating between the primary circuit system 400p and the secondary circuit system 400s.

The first terminal (e.g., a winding start terminal) of the primary coil L21 is connected to the application terminal for the input voltage VBAT. The second terminal (e.g., a winding end terminal) of the primary coil L21 is connected to the drain of the transistor M2. The first terminal (e.g., a winding end terminal) of the secondary coil L22 is connected to the anode of the diode D2. The cathode of the diode D2 and the first terminal of the capacitor C2 are connected to an application terminal for a supply voltage VCC2L. The second terminal (e.g., a winding start terminal) of the secondary coil L22 and the second terminal of the capacitor C2 are both connected to the grounded terminal of the secondary circuit system 400s.

Note that the transistor M2, the transformer TR2, the diode D2, and the capacitor C2 form a flyback switching output stage SWO2 that generates the supply voltage VCC2L for the secondary circuit system 400s from the input voltage VBAT in the primary circuit system 400p while isolating between the primary circuit system 400p and the secondary circuit system 400s.

The overcurrent detection terminal DESAT is connected to the respective first terminals of the resistor R6 and the capacitor C4. The second terminal of the capacitor C4 is connected to the grounded terminal of the secondary circuit system 400s. The second terminal of the resistor R6 is connected to the anode of the diode D4. The cathode of the diode D4 is connected to the drain of the low-side power transistor 2Lu.

The output terminal OUTH is connected to the first terminal of the resistor R7. The output terminal OUTL is connected to the first terminal of the resistor R8. The respective second terminals of the resistors R7 and R8 are connected to the gate of the low-side power transistor 2Lu.

Subsequently, the internal configuration of the driving device 400 will be described referring to FIG. 12. In the following description, unless otherwise noted, description with a focus on the high-side gate driver IC 1Hu will be given. The driving device 400 of this configuration example includes a supply circuit 410, a driving circuit 420, a logic circuit 430, an overcurrent protection circuit 440, and an isolation circuit 450.

The supply circuit 410 forms a flyback power supply that generates the supply voltage VCC2H for the secondary circuit system 400s from the input voltage VBAT in the primary circuit system 400p while isolating between the primary circuit system 400p and the secondary circuit system 400s. Note that, in the low-side gate driver IC 1Lu, the supply voltage VCC2L is generated.

For example, the supply circuit 410 includes a voltage dividing circuit 411, a feedback-signal generating circuit 412, a switching-drive control circuit 413, and a driver 414.

The voltage dividing circuit 411 generates a feedback voltage Vfb by dividing a terminal voltage at the power terminal VCC2 (corresponding to the supply voltage VCC2H) by a predetermined voltage-dividing ratio DIVH. Note that, in the low-side gate driver IC 1Lu, the supply voltage VCC2L is divided by a predetermined voltage-dividing ratio DIVL.

The feedback-signal generating circuit 412 generates a feedback signal FB with pulse information (e.g., a duty cycle) according to the feedback voltage Vfb. For example, the duty cycle of the feedback signal FB (corresponding to a proportion of the on-period in a pulse cycle) becomes lower as the feedback voltage Vfb becomes higher and becomes higher as the feedback voltage Vfb becomes higher. The feedback signal FB may be transmitted from the feedback-signal generating circuit 412 in the secondary circuit system 400s to the switching-drive control circuit 413 in the primary circuit system 400p via the logic circuit 430 and the isolation circuit 450.

The switching-drive control circuit 413 drives the driver 414 according to the feedback signal FB to perform duty control of a gate-driving signal G1 to be applied to the gate-driving terminal FETG. The phase compensation circuit PCI may be externally connected as oscillation prevention means to the switching-drive control circuit 413. Note that, in the low-side gate driver IC 1Lu, duty control of a gate-driving signal G2 is performed according to the feedback signal FB.

Moreover, the switching-drive control circuit 413 also has a function to limit a primary current I1 that flows through the primary coil L11 by monitoring a sense voltage V11 to be applied to the sense terminal SENSE. In the low-side gate driver IC 1Lu, a primary current I2 that flows through the primary coil L21 is limited according to a result of monitoring of a sense voltage V21.

The feedback-signal generating circuit 412 and the switching-drive control circuit 413 described above can be understood as an output feedback circuit that controls the supply voltage VCC2H according to the feedback voltage Vfb so that the supply voltage VCC2H matches a target value. Note that, in the low-side gate driver IC 1Lu, the output feedback control is performed according to the feedback voltage Vfb so that the supply voltage VCC2L matches a target value.

The driver 414 generates the gate-driving signal G1 according to instructions from the switching-drive control circuit 413. For example, the driver 414 includes a transistor P1 and a transistor N1. The transistor P1 may be of a P-channel type. The transistor N1 may be of an N-channel type. The source and the backgate of the transistor P is connected to an application terminal for a supply voltage VCC1. The source and the backgate of the transistor N1 is connected to the grounded terminal of the primary circuit system 400p. The respective gates of the transistors P1 and N1 are connected to the switching-drive control circuit 413. The respective drains of the transistors P1 and N1 are connected to the gate-driving terminal FETG.

The basic operation of the switching output stage SWO1 will be described. The switching output stage SWO1 generates the supply voltage VCC2H from a secondary voltage V12 to be induced in the secondary coil L12 of the transformer TR1 by driving the primary current I1 to flow through the primary coil L11 of the transformer TR1.

For example, an on-period of the transistor M1, the primary current I1 flows from the application terminal for the input voltage VBAT through the primary coil L11 and the transistor M1. Thus, electric energy is stored in the primary coil L11. Then, in response to turning off of the transistor M1, the secondary voltage V12 is induced in the secondary coil L12 that has been electromagnetically coupled to the primary coil L11. The secondary voltage V12 is rectified and smoothed via the diode D1 and the capacitor C1. By such a rectification smoothing operation, the supply voltage VCC2H is generated from the secondary voltage V12. Subsequently, in response to turning on/off of the transistor M1, the switching output operation as described above is repeated. Note that, in the low-side gate driver IC 1Lu, the supply voltage VCC2L is generated by the switching output stage SWO2.

In this way, the driving device 400 including the isolation supply circuit 410 eliminates the need for preparing another power supply IC as means for generating the supply voltages VCC2H and VCC2L for the secondary circuit system 400s.

The driving circuit 420 generates a gate-driving signal GH for the high-side power transistor 2Hu by being supplied with the supply voltage VCC2H from the power terminal VCC2. For example, the driving circuit 420 includes buffers 421 and 422 and transistors 423 and 424. The transistor 423 may be of a P-channel type. The transistor 424 may be of an N-channel type.

The buffer 421 outputs a control signal SP to the gate of the transistor 423 in response to the control signal SP from the logic circuit 430. For example, the control signal SP may be at low level under a state in which a driving pulse signal PWM is at high level. On the other hand, the control signal SP may be at high level under a state in which the driving pulse signal PWM is at low level.

The buffer 422 outputs a control signal SN to the gate of the transistor 424 in response to the control signal SN from the logic circuit 430. For example, the control signal SN may be at low level under the state in which the driving pulse signal PWM is at high level. On the other hand, the control signal SN may be at high level under the state in which the driving pulse signal PWM is at low level.

The transistor 423 switches the path between the application terminal for the supply voltage VCC2H and the output terminal OUTH between a conducting state and a cut-off state according to the control signal SP. Under a state in which the control signal SP is at low level, the transistor 423 is turned on. At this time, the gate-driving signal GH is at high level (˜VCC2H). Note that, in the low-side gate driver IC 1Lu, high level of a gate-driving signal GL corresponds to the supply voltage VCC2L.

The transistor 424 switches the path between the output terminal OUTL and the grounded terminal between a conducting state and a cut-off state according to the control signal SN. Under a state in which the control signal SN is at low level, the transistor 424 is turned on. At this time, the gate-driving signal GH is at low level (˜GND2).

In this way, the transistors 423 and 424 function as a gate-driving half-bridge output stage (a CMOS [complementary MOS] inverter stage).

The logic circuit 430 controls the driving circuit 420 according to signals to be input respectively to the input terminals INA and INB (hereinafter, for the sake of convenience, referred to as input signals INA and INB, which share the same reference symbols as those of the input terminals INA and INB). In terms of what is shown in the diagram, the logic circuit 430 includes a first logic circuit 431 that is provided in the primary circuit system 400p, and a second logic circuit 432 that is provided in the secondary circuit system 400s together with the driving circuit 420 and the overcurrent protection circuit 440.

The first logic circuit 431 generates the driving pulse signal PWM according to the input signals INA and INB. For example, under a state in which INB=H (a logic level indicating a disabled state) is established, PWM=L (a fixed value) is established. On the other hand, under a state in which INB=L (a logic level indicating an enabled state) is established, PWM=INA is established. The driving pulse signal PWM is transmitted to the second logic circuit 432 via the isolation circuit 450.

Note that the input terminal INA of the high-side gate driver IC 1Hu and the input terminal INB of the low-side gate driver IC 1Lu may be short-circuited to each other. Likewise, the input terminal INB of the high-side gate driver IC 1Hu and the input terminal INA of the low-side gate driver IC 1Lu may be short-circuited to each other.

Moreover, the first logic circuit 431 also has a function to perform serial communication according to a predetermined communication protocol between the first logic circuit 431 and the ECU 3 via, for example, the chip select terminal CSB, the clock input terminal SCLK, the serial-data input terminal SDI, and the serial-data output terminal SDO. The communication protocol may be, for example, an SPI [serial peripheral interface] communication protocol. Note that the first logic circuit 431 may have a function to switch from a normal mode to an active discharge mode via the serial communication (details will be given later).

The second logic circuit 432 generates the control signals SP and SN for the driving circuit 420 according to the driving pulse signal PWM to be input via the isolation circuit 450. Thus, the transistors 423 and 424 are turned on/off according to the driving pulse signal PWM. As a result, the gate of the high-side power transistor 2Hu that is connected to the output terminals OUTH and OUTL is driven.

Moreover, the second logic circuit 432 has a function to temporarily stop driving the gate of the high-side power transistor 2Hu according to an overcurrent detection signal OCP. Furthermore, the second logic circuit 432 may have a function to switch from the normal mode to the active discharge mode via the mode switching terminals DCHGEN and DCHGIN (details will be given later).

The overcurrent protection circuit 440 performs an overcurrent protection operation by monitoring whether or not a drain-to-source voltage Vds (2Hu) across the high-side power transistor 2Hu has been saturated. The overcurrent protection circuit 440 includes a comparator 441, a transistor 442, and a current source 443. The transistor 442 may be of an N-channel type. Note that, in the low-side gate driver IC 1Lu, whether or not a drain-to-source voltage Vds (2Lu) across the low-side power transistor 2Lu has been saturated is monitored.

The comparator 441 generates the overcurrent detection signal OCP by comparing a terminal voltage V3 of the overcurrent detection terminal DESAT, the terminal voltage V3 being input to an inverting input terminal (−) and a threshold voltage VthH to be input to a non-inverting input terminal (+) with each other. Note that, in the low-side gate driver IC 1Lu, a terminal voltage V4 of the overcurrent detection terminal DESAT and a threshold voltage VthL are compared with each other.

The transistor 442 is connected between the overcurrent detection terminal DESAT and the grounded terminal. The transistor 442 is turned off under a state in which the overcurrent protection circuit 440 is active and in which the high-side power transistor 2Hu is turned on. On the other hand, the transistor 442 is turned on under a state in which the overcurrent protection circuit 440 is active and in which the high-side power transistor 2Hu is turned off. Moreover, the transistor 442 is turned on also under a state in which the overcurrent protection circuit 440 is inactive.

The current source 443 is connected between the application terminal for the supply voltage VCC2H and the overcurrent detection terminal DESAT. The current source 443 is turned on under a state in which the overcurrent protection circuit 440 is active. On the other hand, the current source 443 is turned off under a state in which the overcurrent protection circuit 440 is inactive.

The isolation circuit 450 transmits signals between the first logic circuit 431 and the second logic circuit 432 while isolating between the primary circuit system 400p and the secondary circuit system 400s. For example, the isolation circuit 450 transmits the driving pulse signal PWM from the first logic circuit 431 to the second logic circuit 432. Moreover, the isolation circuit 450 transmits the feedback signal FB from the second logic circuit 432 to the first logic circuit 431. Furthermore, the isolation circuit 450 may transmit mode switching commands, setting parameters, and the like from the first logic circuit 431 to the second logic circuit 432. The isolation circuit 450 may include a transformer and a capacitor as isolation devices.

Note that the driving device 400 is formed by sealing a first chip 401, a second chip 402, and a third chip 403 in a single package.

The first chip 401 is a semiconductor chip in which circuit devices of the primary circuit system 400p, the circuit devices operating by being supplied with the supply voltage VCC1, are integrated. For example, part of the supply circuit 410 (the switching-drive control circuit 413 and the driver 414) and the first logic circuit 431 can be integrated in the first chip 401.

The second chip 402 is a semiconductor chip in which circuit devices of the secondary circuit system 400s, the circuit devices operating by being supplied with the supply voltage VCC2H, are integrated. For example, part of the supply circuit 410 (the voltage dividing circuit 411 and the feedback-signal generating circuit 412), the driving circuit 420, the second logic circuit 432, and the overcurrent protection circuit 440 can be integrated in the second chip 402.

The third chip 403 is a semiconductor chip in which isolation devices for bidirectionally transmitting signals while isolating between the first chip 401 and the second chip 402 are integrated. In particular, the driving device 400 of this configuration example includes, separately from the first chip 401 and the second chip 402, the third chip 403 that incorporates only the isolation devices.

With such a configuration, the first chip 401 and the second chip 402 can each be formed by a common low-to middle-withstand-voltage process (with a withstand voltage of several volts to several tens of volts). This eliminates the need for a dedicated high-withstand-voltage process (with a withstand voltage of several kilovolts) and helps reduce manufacturing costs.

Moreover, the first chip 401 and the second chip 402 can each be fabricated by a time-proven existing process. This eliminates the need for conducting reliability tests anew and contributes to a shortened development period and reduced development costs.

### Active Discharge

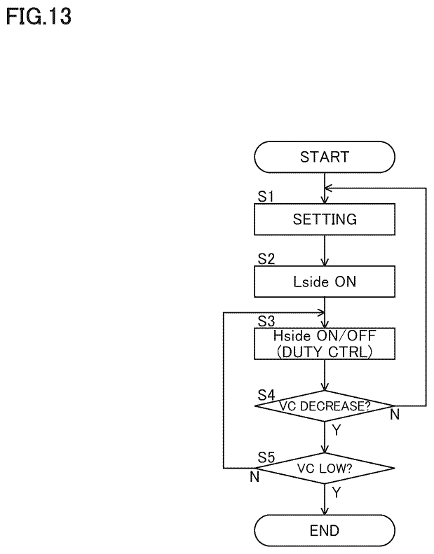

FIG. 13 is a flowchart showing the active discharge. Note that, unless otherwise noted, the ECU 3 can be understood as a subject that controls this flow. Moreover, the high-side gate driver IC 1Hu and the low-side gate driver IC 1Lu, that is, the driving device 400 can be understood as a subject that executes this flow.

The ECU 3 switches each of the high-side gate driver IC 1Hu and the low-side gate driver IC 1Lu from the normal mode (corresponding to a first mode) to the active discharge mode (corresponding to a second mode) via the serial communication according to the SPI communication protocol. The flow is started by such switching control of the operating modes.

In Step S1, respective operating conditions and operating parameters of the high-side gate driver IC 1Hu and the low-side gate driver IC 1Lu are set to those for the active discharge.

First, description will be given with a focus on the high-side gate driver IC 1Hu. In the active discharge mode, high level of the gate-driving signal GH (˜VCC2H), that is, the gate-to-source voltage Vgs (2Hu) to be applied to turn on the high-side power transistor 2Hu is pulled down to be lower than that in the normal mode. For example, the supply circuit 410 of the high-side gate driver IC 1Hu sets the supply voltage VCC2H to a voltage value V31 in the normal mode and sets the supply voltage VCC2H to a voltage value V32 that is less than the voltage value V31 in the active discharge mode.

Note that it is appropriate to set the voltage value V31 that is set in the normal mode to a voltage value that is sufficiently greater than an on-threshold of the high-side power transistor 2Hu. On the other hand, it is appropriate to set the voltage value V32 that is set in the active discharge mode to a voltage value that is slightly greater than the on-threshold of the high-side power transistor 2Hu. For example, when the on-threshold voltage of the high-side power transistor 2Hu ranges from 2.6 to 5.6 V, the voltage value V31 may be set to 15 V, and the voltage value V32 may be set to 8 to 10 V. Note that the voltage values V31 and V32 described above can each be understood as a voltage value with respect to the second supply voltage PVEE (=0 V).

The supply voltage VCC2H may be switched by switching control of the voltage dividing ratio DIVH. For example, the voltage dividing circuit 411 of the high-side gate driver IC 1Hu sets the voltage dividing ratio DIVH to a first voltage-dividing ratio in the normal mode, and sets the voltage dividing ratio DIVH to a second voltage-dividing ratio that is higher than the first voltage-dividing ratio in the active discharge mode. By such switching control of the dividing ratio DIVH, the feedback voltage Vfb is pulled up. Thus, in response to the output feedback control according to the feedback voltage Vfb, the supply voltage VCC2H is pulled down.

Moreover, the overcurrent protection circuit 440 of the high-side gate driver IC 1Hu is activated in the normal mode and deactivated in the active discharge mode. Note that the threshold voltage VthH may be maintained at the same threshold (a first threshold described subsequently) in both the normal mode and the active discharge mode.

Next, description will be given with a focus on the low-side gate driver IC 1Lu. In the active discharge mode, high level of the gate-driving signal GL (˜VCC2L), that is, the gate-to-source voltage Vgs (2Lu) to be applied to turn on the low-side power transistor 2Lu is maintained at the same voltage value as that in the normal mode. For example, the supply circuit 410 of the low-side gate driver IC 1Lu sets the supply voltage VCC2L to the voltage value V31 (e.g., 15 V) in both the normal mode and the active discharge mode. That is, in both the normal mode and the active discharge mode, the voltage dividing circuit 411 of the low-side gate driver IC 1Lu sets the voltage dividing ratio to the first voltage-dividing ratio which is the same as that in the normal mode.

Moreover, the overcurrent protection circuit 440 of the low-side gate driver IC 1Lu is activated in the normal mode and activated or deactivated in the active discharge mode. When the overcurrent protection circuit 440 is activated in the active discharge mode, it is appropriate that the threshold voltage VthL be pulled down to be lower than that in the normal mode. For example, the overcurrent protection circuit 440 of the low-side gate driver IC 1Lu sets the threshold voltage VthL to a first threshold in the normal mode and sets the threshold voltage VthL to a second threshold that is lower than the first threshold in the active discharge mode.

Note that it is appropriate for the first threshold that is set in the normal mode to be set appropriately with consideration given to a magnitude of current that is necessary for driving the motor 4. On the other hand, it is appropriate for the second threshold that is set in the active discharge mode to be set appropriately with consideration given to a magnitude of the discharge current Idchg that is necessary for rapid discharge of the capacitor C (e.g., 1 μs or less). For example, the second threshold may be set to apply overcurrent protection in response to exceeding of the discharge current Idchg above 280 A.

The operating parameters described above, for example, set values of each of the supply voltages VCC2H and VCC2L and the threshold voltages VthH and VthL may be read out of a non-volatile memory that is built into the driving device 400 (unillustrated in FIG. 12), or instructions for the set values may be issued via the serial communication.

Note that there is a risk that switching noise of the high-side power transistor 2Hu causes the overcurrent protection circuit 440 of the low-side gate driver IC 1Lu to yield false positives. In such a case, the overcurrent protection circuit 440 of the low-side gate driver IC 1Lu may be deactivated in the active discharge mode.

Moreover, in both the high-side gate driver IC 1Hu and the low-side gate driver IC 1Lu, the logic circuit 430 enables the input signal INB in the normal mode and disables the input signal INB in the active discharge mode.

For example, in the normal mode, the logic circuit 430 controls the driving circuit 420 so that a switching device to be driven, that is, the high-side power transistor 2Hu or the low-side power transistor 2Lu is turned on under a state in which the input signal INA is at high level and in which the input signal INB is at low level. Moreover, in the normal mode, the logic circuit 430 controls the driving circuit 420 so that the switching device to be driven is turned off under a state in which the input signal INA is at low level or in which the input signal INB is at high level.

Thus, under a state in which the input terminal INA of the high-side gate driver IC 1Hu and the input terminal INB of the low-side gate driver IC 1Lu, and the input terminal INB of the high-side gate driver IC 1Hu and the input terminal INA of the low-side gate driver IC 1Lu each have been short-circuited to each other, the high-side power transistor 2Hu and the low-side power transistor 2Lu can be prevented from being turned on together.

By contrast, in the active discharge mode, the logic circuit 430 controls the driving circuit 420 so that a switching device to be driven is turned on under a state in which the input signal INA is at high level irrespective of the input signal INB. Moreover, in the active discharge mode, the logic circuit 430 controls the driving circuit 420 so that the switching device to be driven is turned off under a state in which the input signal INA is at low level irrespective of the input signal INB.

The process of disabling the input signal INB helps the high-side power transistor 2Hu and the low-side power transistor 2Lu be turned on together in Step S3 described subsequently.

After the series of settings described above has been completed, in Step S2, the low-side power transistor 2Lu is turned on. Note that it is appropriate for the low-side power transistor 2Lu to be kept on until the active discharge of the capacitor C is completed. That is, it is appropriate for the input terminal INA of the low-side gate driver IC 1Lu to be maintained at high level throughout the active discharge.

In Step S3, the high-side power transistor 2Hu is turned on/off. Thus, the high-side power transistor 2Hu and the low-side power transistor 2Lu are cyclically turned on together. As a result, the active discharge of the capacitor C is performed via the high-side power transistor 2Hu and the low-side power transistor 2Lu.

Note that, in order that the high-side power transistor 2Hu is turned on/off, it is appropriate for the ECU 3 to output a signal to be pulse-driven between high level and low level to the input terminal INA of the high-side gate driver IC 1Hu.

Moreover, the ECU 3 may monitor a terminal-to-terminal voltage VC across the capacitor C during the active discharge of the capacitor C. For example, the ECU 3 may control a duty cycle Don of the high-side power transistor 2Hu according to the terminal-to-terminal voltage VC across the capacitor C. Specifically, the duty cycle Don may be further pulled up as the terminal-to-terminal voltage VC across the capacitor C becomes lower. The duty cycle Don can be defined as a proportion of the on-period Ton in a switching cycle Tsw of the high-side power transistor 2Hu, that is, as Don-Ton/Tsw.

In Step S4, whether or not the terminal-to-terminal voltage VC across the capacitor C has decreased as expected is determined. If a YES determination is made in this step, the flow proceeds to Step S5. On the other hand, if a NO determination is made, the flow returns to Step S1, and the operating parameters are reset. For example, in Step S1, the supply voltage VCC2H may be increased by one stage from its default value (corresponding to the voltage value V32). Note that, although not explicitly shown in the flowchart, in a case where the terminal-to-terminal voltage VC does not decrease even by repeating Steps S1 to S4, the active discharge may be stopped.

In Step S5, whether or not the terminal-to-terminal voltage VC across the capacitor C has decreased to its predetermined target value is determined. If a YES determination is made in this step, the active discharge mode is disengaged to return to the normal mode. On the other hand, if a NO determination is made, the flow returns to Step S3, and the series of active discharge described above is continued.

In summary, in response to the switching to the active discharge mode via the serial communication, the high-side gate driver IC 1Hu sets the supply voltage VCC2H to the voltage value V32 (e.g., 8 to 10 V), and turns on/off the high-side power transistor 2Hu according to the input signal INA. On the other hand, in response to the switching to the active discharge mode via the serial communication, the low-side gate driver IC 1Lu sets the supply voltage VCC2L to the voltage value V31 (e.g., 15 V), and keeps the low-side power transistor 2Lu on according to the input signal INA. By continuously keeping the low-side power transistor 2Lu on, continuous application of a high voltage to the motor 4 can be prevented.

That is, in the active discharge mode, under a state in which the discharge current Idchg that flows in the on-period Ton of the high-side power transistor 2Hu is suppressed, the high-side power transistor 2Hu and the low-side power transistor 2Lu are cyclically turned on together. As a result, while suppressing heating of each of the high-side power transistor 2Hu and the low-side power transistor 2Lu, the active discharge of the capacitor C can be performed.

Note that, as described previously, the driving device 400 incorporates the supply circuit 410 that generates the supply voltage VCC2 for the secondary circuit system 400s. The supply circuit 410 has a relatively high output accuracy (e.g., ±2%). Moreover, the supply voltage VCC2 can be adjusted to any target value via the serial communication.

Thus, in the driving device 400 to be used as the high-side gate driver IC 1Hu, by utilizing the supply circuit 410 having the high output accuracy, the gate-to-source voltage Vgs (2Hu) across the high-side power transistor 2Hu, that is, the capability to allow the discharge current Idchg to flow can optionally be adjusted. Thus, the active discharge of the capacitor C can be performed while suppressing the discharge current Idchg.

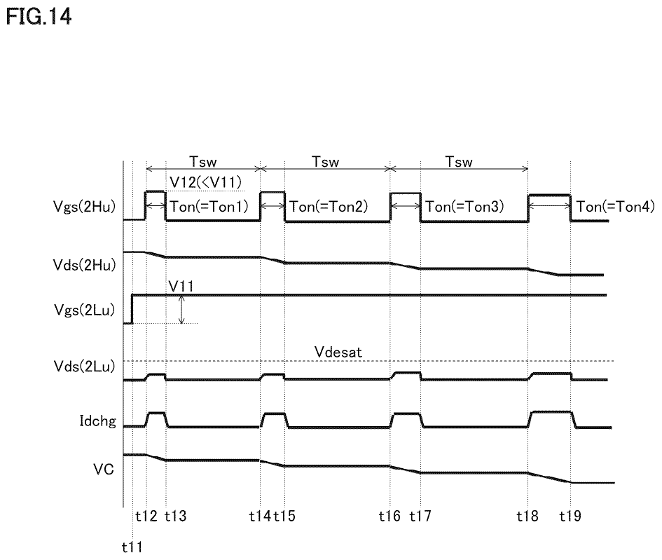

FIG. 14 is a chart showing a first example of the active discharge (case where the overcurrent is not detected). From top down in the chart, the gate-to-source voltage Vgs (2Hu) and the drain-to-source voltage Vds (2Hu) across the high-side power transistor 2Hu, the gate-to-source voltage Vgs (2Lu) and the drain-to-source voltage Vds (2Lu) across the low-side power transistor 2Lu, the discharge current Idchg, and the terminal-to-terminal voltage VC across the capacitor C are shown.

In the active discharge mode, at a time t11, the gate-to-source voltage Vgs (2Lu) across the low-side power transistor 2Lu is raised to high level. Note that, high level of the gate-to-source voltage Vgs (2Lu) is set to the voltage value V31 (e.g., 15 V). Thus, the low-side power transistor 2Lu is turned on, specifically, is in a full-on state in which an on-resistance value is pulled down to a minimum-possible value or a near-minimum-possible value within the device design.

Then, at or after a time t12, the gate-to-source voltage Vgs (2Hu) across the high-side power transistor 2Hu is pulse-driven to high level and low level in the predetermined switching cycle Tsw. The switching cycle Tsw may be, for example, 100 μs.

The high-side power transistor 2Hu is cyclically turned on/off according to the pulse-driving of the gate-to-source voltage Vgs (2Hu). On the other hand, the low-side power transistor 2Lu is continuously kept on. Thus, in the active discharge mode, the high-side power transistor 2Hu and the low-side power transistor 2Lu are cyclically turned on together.

In terms of what is shown in the chart, in the on-periods Ton of the high-side power transistor 2Hu, that is, from times t12 to t13, times t14 to t15, times t16 to t17, and times t18 to t19, the discharge current Idchg flows via the high-side power transistor 2Hu and the low-side power transistor 2Lu. As a result, the terminal-to-terminal voltage VC across the capacitor C decreases in a stepwise pattern.

In this context, high level of the gate-to-source voltage Vgs (2Hu) is set to the voltage value V32 (e.g., 8 to 10 V) that is less than the voltage value V31. Thus, the high-side power transistor 2Hu is turned on, specifically, is in a half-on state in which, although current is allowed to flow, the on-resistance value is not pulled down to the minimum-possible value or the near-minimum-possible value within the device design. Thus, the discharge current Idchg that flows in the on-period Ton can be limited to several tens of amperes (e.g., 60 A) by the high-side power transistor 2Hu.

Incidentally, the drain-to-source voltage Vds (2Hu) across the high-side power transistor 2Hu in the half-on state exceeds a saturation voltage Vdesat, that is, is apparently saturated. Thus, in the active discharge mode, the overcurrent protection circuit 440 of the high-side gate driver IC 1Hu is deactivated. As a result, there is no risk that the active discharge is disturbed. Note that the drain-to-source voltage Vds (2Hu) also decreases in a stepwise pattern as the terminal-to-terminal voltage VC decreases.

On the other hand, the overcurrent protection circuit 440 of the low-side gate driver IC 1Lu is activated even in the active discharge mode. In this chart, the discharge current Idchg is sufficiently suppressed, and the drain-to-source voltage Vds (2Lu) across the low-side power transistor 2Lu falls below the saturation voltage Vdesat. Thus, the overcurrent protection is not applied.

Moreover, it is appropriate that the duty cycle Don of the high-side power transistor 2Hu be pulled up as the terminal-to-terminal voltage VC across the capacitor C decreases. In terms of what is shown in the chart, the on-period Ton of the high-side power transistor 2Hu is extended in a stepwise pattern as the terminal-to-terminal voltage VC decreases (Ton1->Ton2->Ton3->Ton4, note that Ton1<Ton2<Ton3<Ton4). Variable control with respect to the duty cycle Don helps rapidly discharge the capacitor C within a shortest-possible time (e.g., 1 s or less) while controlling power consumption, that is, a heat generation amount in the half-bridge output stage 2u.

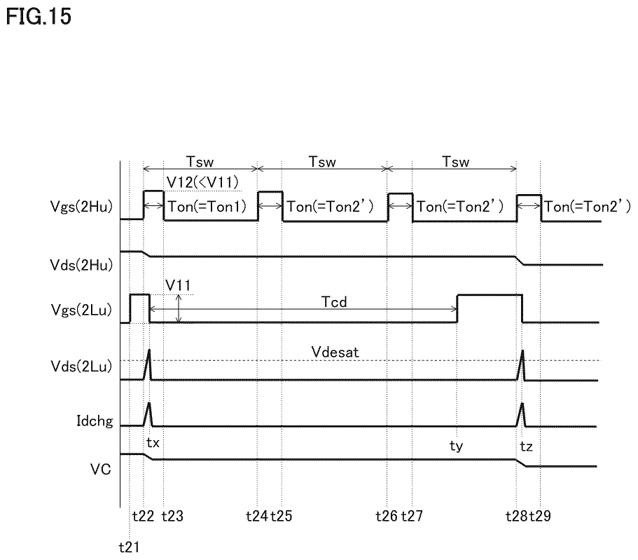

FIG. 15 is a chart showing a second example of the active discharge (case where the overcurrent is detected). As in FIG. 14 referred to previously, from top down in the chart, the gate-to-source voltage Vgs (2Hu) and the drain-to-source voltage Vds (2Hu) across the high-side power transistor 2Hu, the gate-to-source voltage Vgs (2Lu) and the drain-to-source voltage Vds (2Lu) across the low-side power transistor 2Lu, the discharge current Idchg, and the terminal-to-terminal voltage VC across the capacitor C are shown.

In the active discharge mode, after the gate-to-source voltage Vgs (2Lu) is raised to high level at a time t21, the gate-to-source voltage Vgs (2Hu) is pulse-driven at or after a time t22. This is not significantly different from the first example (case where the overcurrent is not detected).

Note that, in a case where the discharge current Idchg which is excessively high flows during the active discharge, as at a time tx, the drain-to-source voltage Vds (2Lu) across the low-side power transistor 2Lu exceeds the saturation voltage Vdesat. At this time, the overcurrent protection circuit 440 of the low-side gate driver IC 1Lu operates to forcibly drop the gate-to-source voltage Vgs (2Lu) to low level. As a result, the low-side power transistor 2Lu is forcibly turned off to cut off the discharge current Idchg. Moreover, at a time point when the discharge current Idchg is cut off, the drain-to-source voltage Vds (2Hu) stops decreasing. Likewise, the terminal-to-terminal voltage VC across the capacitor C also stops decreasing (stops being discharged).

Note that it is appropriate for the low-side power transistor 2Lu to be kept off until a cool down period Ted elapses. During that time, the discharge current Idchg does not flow even when the high-side power transistor 2Hu is cyclically turned on. Moreover, in the cool down period Tcd, the active discharge of the capacitor C is temporarily stopped, and hence the terminal-to-terminal voltage VC stops decreasing. Thus, the duty cycle Don of the high-side power transistor 2Hu is maintained to correspond to a duration (in the chart, Ton2′) according to the terminal-to-terminal voltage VC in the cool down period Ted. The cool down period Ted may optionally be adjusted via the serial communication.

After the cool down period Ted ends at a time ty, the low-side power transistor 2Lu is turned on again. Then, at a time t28 when the high-side power transistor 2Hu is switched on, the discharge current Idchg starts to flow again. That is, the active discharge of the capacitor C is retried.

Note that, in a case where a cause of the overcurrent has not yet been resolved, as at a time tz, the drain-to-source voltage Vds (2Lu) across the low-side power transistor 2Lu exceeds the saturation voltage Vdesat again. As a result, the overcurrent protection described previously is applied to cut off the discharge current Idchg again. Note that, in a case where the overcurrent protection and the return are repeated again and again, the active discharge may be stopped by prioritizing safety of the system.

### Mode Switching Terminals

Note that, in the above description, the operating modes of the driving device 400 are switched via the serial communication. Alternatively, the operating modes of the driving device 400 may be switched via the mode switching terminals DCHGEN and DCHGIN.

For example, the driving device 400 may be switched from the normal mode to the active discharge mode under a state in which the mode switching terminals DCHGEN and DCHGIN are both at high level. On the other hand, the driving device 400 may be maintained in the normal mode under a state in which at least one of the mode switching terminals DCHGEN and DCHGIN is at low level. Such a configuration prevents switching to the active discharge mode even in response to superimposition of noise on one of the mode switching terminals DCHGEN and DCHGIN.

For example, in response to the switching to the active discharge mode via the mode switching terminals DCHGEN and DCHGIN, the high-side gate driver IC 1Hu may set the supply voltage VCC2H to the voltage value V32 (e.g., 8 to 10 V), and may autonomously turn on/off the high-side power transistor 2Hu irrespective of the input signals INA and INB.

On the other hand, in response to the switching to the active discharge mode via the mode switching terminals DCHGEN and DCHGIN, the low-side gate driver IC 1Lu may set the supply voltage VCC2L to the voltage value V31 (e.g., 15 V), and may autonomously keep the low-side power transistor 2Lu on irrespective of the input signals INA and INB.

Such a configuration helps perform the active discharge of the capacitor C even in a situation where the serial communication with the ECU 3 is not performed.

### Application to Vehicle

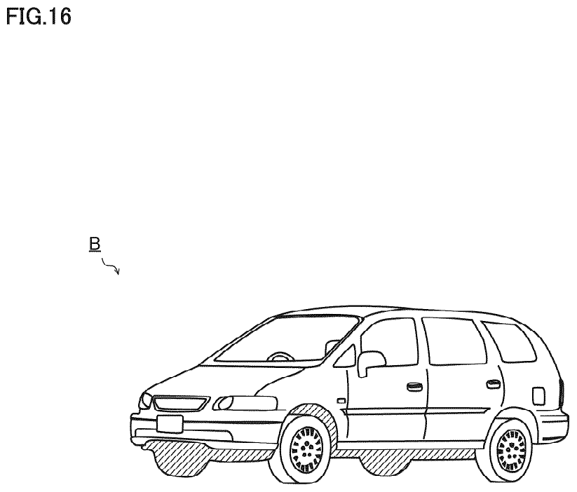

FIG. 16 is an exterior view of a vehicle. The vehicle B of this configuration example incorporates various electronic devices that operate by being supplied with power from a battery.

The vehicle B may be an engine vehicle or may be an electric vehicle (an xEV such as a BEV [battery electric vehicle], an HEV [hybrid electric vehicle], a PHEV/PHV [plug-in hybrid electric vehicle/plug-in hybrid vehicle], or an FCEV/FCV [fuel cell electric vehicle/fuel cell vehicle]).

Note that the signal transmission device 200 and the driving device 4 described previously may be installed in any of the electronic devices to be incorporated in the vehicle B.

### APPENDICES

The driving device according to the present disclosure helps discharge a capacitor even without the need for a discharge circuit. In the following description, appendices of the present disclosure are provided.

### Appendix 1

A driving device (400), including:
a supply circuit (410) configured to generate a supply voltage (VCC2H, VCC2L);
a driving circuit (420) configured to generate a driving signal (GH, GL) for a switching device (2Hu, 2Lu) by being supplied with the supply voltage (VCC2H, VCC2L); and
a logic circuit (430) configured to control the driving circuit (420) according to a first input signal (INA) and a second input signal (INB), in which
the supply circuit (410) sets the supply voltage (VCC2H, VCC2L) to a first voltage value (V31) in a first mode (normal mode), and sets the supply voltage (VCC2H, VCC2L) to one of a second voltage value (V32) that is less than the first voltage value (V31) and the first voltage value (V31) in a second mode (active discharge mode), and
the logic circuit (430) enables the second input signal (INB) in the first mode, and disables the second input signal (INB) in the second mode.

### Appendix 2

The driving device (400) according to Appendix 1, in which
the logic circuit (430) controls, in the first mode, the driving circuit (420) so that the switching device (2Hu, 2Lu) is turned on under a state in which the first input signal (INA) is at a first logic level (e.g., H) and in which the second input signal (INB) is at a second logic level (e.g., L), and so that the switching device (2Hu, 2Lu) is turned off under one of a state in which the first input signal (INA) is at the second logic level (e.g., L) and a state in which the second input signal (INB) is at the first logic level (e.g., H), and
the logic circuit (430) controls, in the second mode, the driving circuit (420) so that the switching device (2Hu, 2Lu) is turned on under a state in which the first input signal (INA) is at the first logic level (e.g., H) irrespective of the second input signal (INB), and so that the switching device (2Hu, 2Lu) is turned off under the state in which the first input signal (INA) is at the second logic level (e.g., L) irrespective of the second input signal (INB).

### Appendix 3

The driving device (400) according to Appendix 1 or 2, in which
the supply circuit (410) includes
   a voltage dividing circuit (411) configured to generate a feedback voltage (Vfb) by dividing the supply voltage (VCC2H, VCC2L) by a predetermined voltage-dividing ratio, and
   an output feedback circuit (412, 413) configured to control the supply voltage (VCC2H, VCC2L) according to the feedback voltage (Vfb), and
the voltage dividing circuit (411) sets the voltage dividing ratio to a first voltage-dividing ratio in the first mode and sets the voltage dividing ratio to one of a second voltage-dividing ratio that is higher than the first voltage-dividing ratio and the first voltage-dividing ratio in the second mode.

### Appendix 4

The driving device (400) according to any of Appendices 1 to 3, further including
an overcurrent protection circuit (440) configured to perform an overcurrent protection operation by monitoring whether or not a terminal-to-terminal voltage across the switching device (2Hu, 2Lu) has been saturated, in which
the overcurrent protection circuit (440) is activated in the first mode and is one of deactivated and activated in the second mode.

### Appendix 5

The driving device (400) according to any of Appendices 1 to 4, in which
the logic circuit (430) includes
   a first logic circuit (431) that is provided in a primary circuit system (400p), and
   a second logic circuit (432) that is provided in a secondary circuit system (400s) together with the driving circuit (420), and
the driving device (400) further includes an isolation circuit (450) configured to transmit signals between the first logic circuit (431) and the second logic circuit (432) while isolating between the primary circuit system (400p) and the secondary circuit system (400s).

### Appendix 6

The driving device (400) according to Appendix 5, in which
the supply circuit (410) forms a flyback power supply configured to generate the supply voltage (VCC2H, VCC2L) for the secondary circuit system (400s) from an input voltage (VBAT) in the primary circuit system (400p) while isolating between the primary circuit system (400p) and the secondary circuit system (400s).

### Appendix 7

An electronic device (A), including:
a high-side switching device (2Hu) and a low-side switching device (2Lu) that form a half-bridge output stage (2u) by being connected in series between an application terminal for a first supply voltage (PVDD) and an application terminal for a second supply voltage (PVEE);
a capacitor (C) that is connected in parallel to the half-bridge output stage (2u) between the application terminal for the first supply voltage (PVDD) and the application terminal for the second supply voltage (PVEE);
a high-side driving device (1Hu) configured to drive the high-side switching device (2Hu);
a low-side driving device (1Lu) configured to drive the low-side switching device (2Lu); and
a control device (3) configured to control the high-side driving device (1Hu) and the low-side driving device (1Lu), in which
the high-side driving device (1Hu) and the low-side driving device (1Lu) are each the driving device (400) according to any of Appendices 1 to 6.

### Appendix 8

The electronic device (A) according to Appendix 7, in which
the control device (3) switches each of the high-side driving device (1Hu) and the low-side driving device (1Lu) to one of the first mode and the second mode via serial communication according to a predetermined communication protocol.

### Appendix 9

The electronic device (A) according to Appendix 8, in which,
in response to the switching to the second mode via the serial communication, the high-side driving device (1Hu) sets the supply voltage (VCC2H) to the second voltage value (V32), and turns on/off the high-side switching device (2Hu) according to the first input signal (INA), and,
in response to the switching to the second mode via the serial communication, the low-side driving device (1Lu) sets the supply voltage (VCC2L) to the first voltage value (V31), and keeps the low-side switching device (2Lu) on according to the first input signal (INA).

### Appendix 10

The electronic device (A) according to Appendix 9, in which
the control device (3) controls a duty cycle of the high-side switching device (2Hu) according to a terminal-to-terminal voltage across the capacitor (C).

### Appendix 11

The electronic device (A) according to any of Appendices 7 to 10, in which
the driving device (400) includes a mode switching terminal (DCHGEN, DCHGIN),
in response to switching to the second mode via the mode switching terminal (DCHGEN, DCHGIN), the high-side driving device (1Hu) sets the supply voltage (VCC2H) to the second voltage value (V32), and autonomously turns on/off the high-side switching device (2Hu), and,
in response to the switching to the second mode via the mode switching terminal (DCHGEN, DCHGIN), the low-side driving device (1Lu) sets the supply voltage (VCC2L) to the first voltage value (V31), and autonomously keeps the low-side switching device (2Lu) on.

### Appendix 12

A vehicle (B), including the electronic device (A) according to any of Appendices 7 to 11.

### OTHER MODIFICATIONS

Note that the various technical features disclosed herein may be implemented in any manners other than those in the embodiments described above and allow for various modifications without departure from the spirit of their technical ingenuity. That is, the embodiments described above should be understood to be illustrative and not restrictive in every aspect. Moreover, it should be understood that the technical scope of the present disclosure is defined by the appended claims and encompasses any modifications within a scope and sense equivalent to those claims.

What is claimed is:

1. A driving device, comprising:
a supply circuit configured to generate a supply voltage;
a driving circuit configured to generate a driving signal for a switching device by being supplied with the supply voltage; and
a logic circuit configured to control the driving circuit according to a first input signal and a second input signal, wherein
the supply circuit sets the supply voltage to a first voltage value in a first mode, and sets the supply voltage to one of a second voltage value that is less than the first voltage value and the first voltage value in a second mode, and
the logic circuit enables the second input signal in the first mode and disables the second input signal in the second mode.

2. The driving device according to claim 1, wherein
the logic circuit controls, in the first mode, the driving circuit so that the switching device is turned on under a state in which the first input signal is at a first logic level and in which the second input signal is at a second logic level, and so that the switching device is turned off under one of a state in which the first input signal is at the second logic level and a state in which the second input signal is at the first logic level, and
the logic circuit controls, in the second mode, the driving circuit so that the switching device is turned on under a state in which the first input signal is at the first logic level irrespective of the second input signal, and so that the switching device is turned off under the state in which the first input signal is at the second logic level irrespective of the second input signal.

3. The driving device according to claim 1, wherein
the supply circuit includes
a voltage dividing circuit configured to generate a feedback voltage by dividing the supply voltage by a predetermined voltage-dividing ratio, and
an output feedback circuit configured to control the supply voltage according to the feedback voltage, and
the voltage dividing circuit sets the voltage dividing ratio to a first voltage-dividing ratio in the first mode and sets the voltage dividing ratio to one of a second voltage-dividing ratio that is higher than the first voltage-dividing ratio and the first voltage-dividing ratio in the second mode.

4. The driving device according to claim 1, further comprising
an overcurrent protection circuit configured to perform an overcurrent protection operation by monitoring whether or not a terminal-to-terminal voltage across the switching device has been saturated, wherein
the overcurrent protection circuit is activated in the first mode and is one of deactivated and activated in the second mode.

5. The driving device according to claim 1, wherein
the logic circuit includes
a first logic circuit that is provided in a primary circuit system, and
a second logic circuit that is provided in a secondary circuit system together with the driving circuit, and
the driving device further includes an isolation circuit configured to transmit signals between the first logic circuit and the second logic circuit while isolating between the primary circuit system and the secondary circuit system.

6. The driving device according to claim 5, wherein
the supply circuit forms a flyback power supply configured to generate the supply voltage for the secondary circuit system from an input voltage in the primary circuit system while isolating between the primary circuit system and the secondary circuit system.

7. An electronic device, comprising:
a high-side switching device and a low-side switching device that form a half-bridge output stage by being connected in series between an application terminal for a first supply voltage and an application terminal for a second supply voltage;
a capacitor that is connected in parallel to the half-bridge output stage between the application terminal for the first supply voltage and the application terminal for the second supply voltage;
a high-side driving device configured to drive the high-side switching device;
a low-side driving device configured to drive the low-side switching device; and
a control device configured to control the high-side driving device and the low-side driving device, wherein
the high-side driving device and the low-side driving device are each the driving device according to claim 1.

8. The electronic device according to claim 7, wherein
the control device switches each of the high-side driving device and the low-side driving device to one of the first mode and the second mode via serial communication according to a predetermined communication protocol.

9. The electronic device according to claim 8, wherein,
in response to the switching to the second mode via the serial communication, the high-side driving device sets the supply voltage to the second voltage value, and turns on/off the high-side switching device according to the first input signal, and,
in response to the switching to the second mode via the serial communication, the low-side driving device sets the supply voltage to the first voltage value and keeps the low-side switching device on according to the first input signal.

10. The electronic device according to claim 9, wherein
the control device controls a duty cycle of the high-side switching device according to a terminal-to-terminal voltage across the capacitor.

11. The electronic device according to claim 7, wherein
the driving device includes a mode switching terminal,
in response to switching to the second mode via the mode switching terminal, the high-side driving device sets the supply voltage to the second voltage value, and autonomously turns on/off the high-side switching device, and,
in response to the switching to the second mode via the mode switching terminal, the low-side driving device sets the supply voltage to the first voltage value and autonomously keeps the low-side switching device on.

12. A vehicle, comprising the electronic device according to claim 7.
